(19) United States
(12) Patent Application Publication
(10) Pub. No.: US 2025/0322870 A1
(43) Pub. Date: Oct. 16, 2025

(54) In-Memory AI Inference with Multi-state Weight based on Vertical Domain Control

(71) Applicant: Western Digital Technologies, Inc., San Jose, CA (US)

(72) Inventors: Quang LE, San Jose, CA (US); Xiaoyong LIU, San Jose, CA (US); Lei XU, San Jose, CA (US); Hassan OSMAN, San Jose, CA (US); Son T. LE, San Jose, CA (US); Hisashi TAKANO, Fujisawa-shi (JP)

(73) Assignee: Western Digital Technologies, Inc., San Jose, CA (US)

(21) Appl. No.: 19/247,436

(22) Filed: Jun. 24, 2025

Related U.S. Application Data
(63) Continuation-in-part of application No. 18/954,415, filed on Nov. 20, 2024.
Application No. 18/954,415 is a continuation-in-part of application No. 17/172,155, filed on Feb. 10, 2021, now Pat. No. 12,314,842.

(51) Int. Cl. G11C 11/56; G11C 11/16; G11C 11/54; H10B 61/00

(52) U.S. Cl. CPC G11C 11/5607; G11C 11/161; G11C 11/54; H10B 61/20

(57) ABSTRACT

The present disclosure is generally related to a deep neural network (DNN) device comprising a plurality of spin-orbit torque (SOT) cells. The DNN device comprises an array comprising n rows and m columns of nodes, each row of nodes coupled to one of n first conductive lines, each column of nodes coupled to one of m second conductive lines, each node of the n rows and m columns of nodes comprising a plurality of SOT cells, each SOT cell comprising: a SOT layer, a ferromagnetic layer comprising two or more magnetic domains, and a plurality of etch control layers. The etch control layers have different etching rates and are used to create domain walls between the two or more magnetic domains. The DNN device further comprises a controller configured to store at least one corresponding of a neural network in each of the two or more magnetic domains.

### CROSS-REFERENCE TO RELATED APPLICATIONS

This application is a continuation-in-part of co-pending U.S. patent application Ser. No. 18/954,415, filed Nov. 20, 2024, which is a continuation-in-part of U.S. Pat. No. 12,314,842, issued May 27, 2025. Each of the aforementioned related patent applications is herein incorporated by reference.

### BACKGROUND OF THE DISCLOSURE

### Field of the Disclosure

Embodiments of the present disclosure generally relate to a deep neural network (DNN) device utilizing a plurality of spin-orbit torque (SOT) cells.

### Description of the Related Art

Deep neural networks (DNNs) are a promising and quickly evolving area of technology utilized in artificial intelligence (AI). DNNs are composed of multiple layers (two or more) between the input and final output layers. DNNs transform data at each layer, creating a new representation of the output of each layer. Generally, when a DNN is under training, many of its parameter weights are updated, and during inference, the DNN's parameter weights are already fixed by pre-training. When DNNs are used for inference, the states/values of weights are known. In implementations where non-volatile memory cells are configured for DNN applications with weights stored in the cells, the amount and magnitude of current needed to set or read the states from the cells is known as well.

A core feature of many DNNs involves matrix multiplication/summation followed by an activation function (e.g., a non-linear transfer function). Many DNNs currently rely solely on a traditional computing architecture with discrete memory and processor components to perform both the matrix multiplication/summation and the activation function. Traditional Von Neumann architecture-based implementations of a DNN generally require more data movement between the main memory and a CPU/GPU, which is more power/memory-consuming and slower. Hardware compute-in-memory implementations of DNNs promise lower energy, non-linearity, and higher density for Al applications. However, the current compute-in-memory hardware implementations of DNN are still limited.

Therefore, there is a need in the art for new hardware implementations for DNNs for inference.

### SUMMARY OF THE DISCLOSURE

The present disclosure is generally related to a deep neural network (DNN) device comprising a plurality of spin-orbit torque (SOT) cells. The DNN device comprises an array comprising n rows and m columns of nodes, each row of nodes coupled to one of n first conductive lines, each column of nodes coupled to one of m second conductive lines, each node of the n rows and m columns of nodes comprising a plurality of SOT cells, each SOT cell comprising: a SOT layer, a ferromagnetic (FM) layer comprising two or more domains, and a plurality of etch control layers. The etch control layers have different etching rates and are used to create domain walls between the two or more magnetic domains. The DNN device further comprises a controller configured to store at least one corresponding weight of an n×m array of weights of a neural network in each of the two or more magnetic domains.

In one embodiment, a deep neural network (DNN) device, the DNN device comprising an array comprising n rows and m columns of nodes, each row of nodes coupled to one of n first conductive lines, each column of nodes coupled to one of m second conductive lines, each node of the n rows and m columns of nodes comprising a spin orbit torque (SOT) cell, the SOT cell comprising: a SOT layer, a ferromagnetic (FM) layer having a first surface disposed in contact with the SOT layer, the FM layer comprising two or more magnetic domains, two or more first etch control layers disposed in contact with a second surface and a third surface of each of the two or more magnetic domains, and one or more second etch control layers disposed between each of the two or more magnetic domains, the one or more second etch control layers being disposed in contact with the second and third surfaces of the two or more magnetic domains, wherein the one or more second etch control layers have a slower etching rate than the two or more first etch control layers, and a controller configured to store at least one corresponding weight of an n×m array of weights of a neural network using the two or more magnetic domains.

In another embodiment, a deep neural network (DNN) device, the DNN device comprising a plurality of spin orbit torque (SOT) cells, each SOT cell comprising: a SOT layer, a ferromagnetic (FM) layer having a first surface disposed in contact with the SOT layer, the FM layer comprising two or more magnetic domains, two or more first etch control layers disposed in contact with a second surface and a third surface of each of the two or more magnetic domains, the two or more first etch control layers being disposed adjacent to a top and bottom of the two or more magnetic domains, and one or more second etch control layers disposed in contact with the second and third surface of the two or more magnetic domains, the one or more second etch control layers being disposed adjacent to a center of each of the two or more magnetic domains, wherein the one or more second etch control layers have a faster etching rate than the two or more first etch control layers, and a controller configured to store a weight of a neural network using the two or more magnetic domains.

In yet another embodiment a spin orbit torque (SOT) cell comprising: a SOT layer, a ferromagnetic (FM) layer having a first surface disposed in contact with the SOT layer, the FM layer comprising two or more magnetic domains, two or more first etch control layers disposed in contact with a second surface and a third surface of each of the two or more magnetic domains, the two or more first etch control layers being disposed adjacent to a top and bottom of the two or more magnetic domains, and one or more second etch control layers disposed in contact with the second and third surface of the two or more magnetic domains, the one or more second etch control layers being disposed adjacent to a center of each of the two or more magnetic domains, wherein the one or more second etch control layers have a higher Si concentration than the two or more first etch control layers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A depicts an embodiment of a memory system and a host.

FIG. 1B depicts an embodiment of memory core control circuits.

FIG. 1C depicts further details of one embodiment of voltage generators.

FIG. 2A shows an example of an artificial neural network.

FIG. 2B depicts a matrix-vector multiplication operation of the artificial neural network of FIG. 2A.

FIG. 2C depicts an embodiment of an apparatus that may be used to perform the matrix-vector multiplication operation depicted in FIG. 2B.

FIG. 3A depicts an embodiment of a cross-point memory array that may be used to perform the matrix-vector multiplication operation depicted in FIG. 2B.

FIG. 3B1 depicts an example spin-orbit torque (SOT) magnetoresistive random-access memory (MRAM) non-volatile memory cell of the apparatus of FIG. 3A.

FIG. 3B2 depicts another example SOT MRAM non-volatile memory cell of the apparatus of FIG. 3A.

FIG. 3C depicts another example SOT MRAM non-volatile memory cell of the apparatus of FIG. 3A.

FIG. 4 illustrates a cross-sectional view of a SOT cell scheme, according to one embodiment.

FIGS. 5A-5C illustrate SOT cells, according to various embodiments.

FIGS. 6A-6C illustrate SOT cells, according to various embodiments.

FIGS. 7A-7B illustrate views of a SOT cell, according to another embodiment.

FIGS. 8A-8B illustrate views of a SOT cell, according to yet another embodiment.

To facilitate understanding, identical reference numerals have been used, where possible, to designate identical elements that are common to the figures. It is contemplated that elements disclosed in one embodiment may be beneficially utilized in other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated for implementation and practice in the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure is generally related to a deep neural network (DNN) device comprising a plurality of spin-orbit torque (SOT) cells. The DNN device comprises an array comprising n rows and m columns of nodes, each row of nodes coupled to one of n first conductive lines, each column of nodes coupled to one of m second conductive lines, each node of the n rows and m columns of nodes comprising a plurality of SOT cells, each SOT cell comprising: a SOT layer, a ferromagnetic (FM) layer comprising two or more magnetic domains, and a plurality of etch control layers. The etch control layers have different etching rates and are used to create domain walls between the two or more magnetic domains. The DNN device further comprises a controller configured to store at least one corresponding weight of an n×m array of weights of a neural network in each of the two or more magnetic domains.

Technology is described for using non-volatile memory cells to perform matrix multiplication in deep neural networks (DNNs). In particular, technology is described for using spin-orbit torque (SOT) non-volatile memory cells to perform matrix-vector multiplication in a neuromorphic computing system. A neuromorphic computing system may be used to implement an artificial neural network.

Matrix-vector multiplication may be performed by taking the dot product of a vector with each column vector of a matrix. A vector dot product is the sum of products of the corresponding elements of two equal length vectors. Accordingly, a non-volatile memory system that performs matrix-vector multiplication also may be referred to as a multiplier-accumulator (MAC).

In an embodiment, a non-volatile memory system includes an array that includes n rows and m columns of nodes, with each node including a non-volatile memory cell. In this regard, the array is an n×m array of non-volatile memory cells. In an embodiment, each row of nodes is coupled to one of n first conductive lines (e.g., word lines), and each column of nodes is coupled to one of m second conductive lines (e.g., bit lines).

In an embodiment, each non-volatile memory cell includes an SOT non-volatile memory cell. Thus, in an embodiment each row of SOT non-volatile memory cells is coupled to one of n first conductive lines (e.g., word lines), and each column of SOT non-volatile memory cells is coupled to one of m second conductive lines (e.g., bit lines).

As used herein, the value of a weight stored in an SOT non-volatile memory cell is also referred to herein as a “multiplicand.” While in some approaches Each SOT non-volatile memory cell can be a “binary non-volatile memory cell,” which is a non-volatile memory cell that can be repeatedly switched between two physical states. Embodiments disclosed herein are directed to multi-state non-volatile memory cells which are non-volatile memory cells that may be repeatedly switched between more than two physical states.

In binary weight DNN implementations, each memory cell in the n×m array of SOT non-volatile memory cells is configured to store one bit of information. In an embodiment, each SOT non-volatile memory cell may be programmed to either a low resistance state (also referred to herein as an “ON state”) or a high resistance state (also referred to herein as an “OFF-state”). In an embodiment, the low resistance state may be used to represent the first weight value (e.g., “1”), and the high resistance state may be used to represent the second weight value (e.g., “0”). In contrast, multi-state weight cells of the disclosed embodiments can have more than two weight values.

In an embodiment, n input voltages (also referred to herein as “multiply voltages”) are applied to the first conductive lines (e.g., word lines). In an embodiment, each of the n multiply voltages represents a single-bit binary input, and has either a first input value (e.g., “1V”) or a second input value (e.g., “0V”). Other binary voltage values may be used for first input value and second input value. In an embodiment, the n multiply voltages constitute an n-element input vector (also referred to herein as a “multiply vector”).

In an embodiment, the memory cells in the n×m array of SOT non-volatile memory cells generate m output currents at the m second conductive lines (e.g., bit lines). In an embodiment, the m output currents constitute a result of multiplying the n-element input vector (multiply vector) by the n×m array of weights stored in the SOT non-volatile memory cells. In an embodiment, each of the m output currents represents a single-bit binary output, and has either a first output value (e.g., “1”) or a second output value (e.g., “0”). In an embodiment, the m output currents constitute an m-element output vector.

In this regard, multiplication is performed by applying a multiply voltage to a node and processing a current from the SOT non-volatile memory cell in the node. In an embodiment, each multiply voltage has a magnitude that represents a multiplier. In an embodiment, the multiply voltage is applied across two terminals of the SOT non-volatile memory cell.

In an embodiment, the SOT non-volatile memory cell responds to the multiply voltage by conducting a memory cell current in the second conductive line (e.g., bit line) coupled to the SOT non-volatile memory cell. The magnitude of the memory cell current represents a product of the multiplier applied to the node and the multiplicand stored in the SOT non-volatile memory cell in the node.

As described above, in an embodiment each SOT non-volatile memory cell may be programmed to either a low resistance ON-state or a high resistance OFF-state, and each of the n multiply voltages has either a first input value (e.g., “1V”) or a second input value (e.g., “0V”). As a result, each of the m output currents represents a single-bit binary output and has either a first output value (e.g., “low current”) or a second output value (e.g., “high current”).

As described above, technology is described for configuring an n×m array of SOT non-volatile memory cells to implement a binary neural network. In an embodiment, each SOT non-volatile memory cell in the array stores a binary weight, n binary inputs may be applied to the first conductive lines, and m binary outputs may be generated at the second conductive lines.

As used herein, “multiplier” is used for the magnitude of the multiply voltage, and “multiplicand” is used for the value of the weight stored in the SOT non-volatile memory cell in the node. This is for the convenience of discussion. The terms “multiplier” and “multiplicand” are interchangeable.

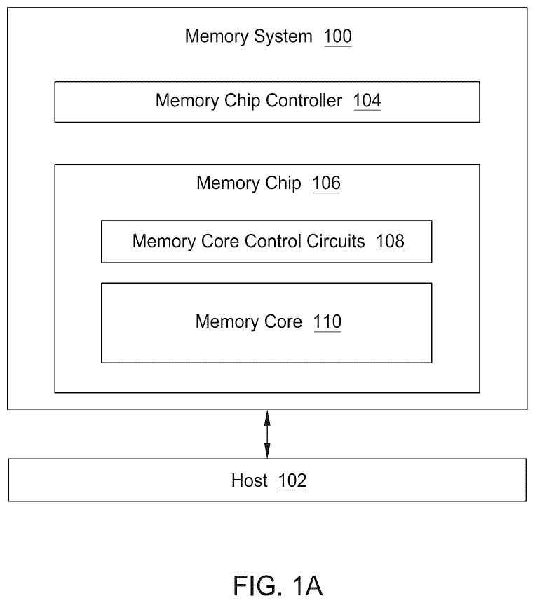

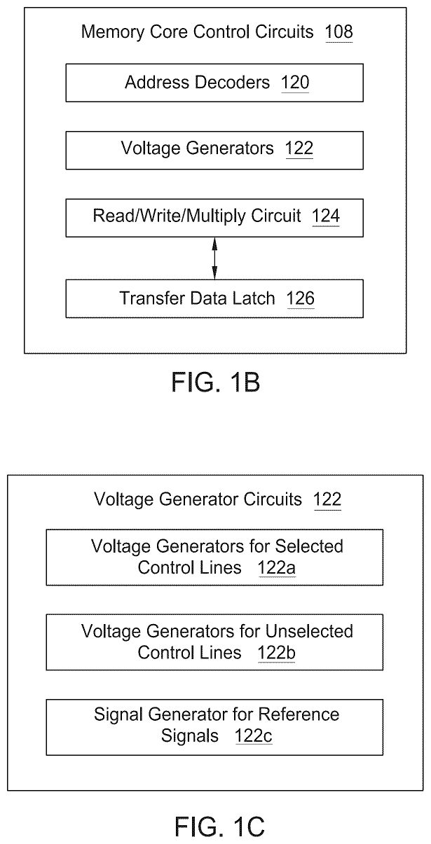

An example memory system 100 in which embodiments may be practiced will be discussed. FIG. 1A depicts an embodiment of a memory system 100 and a host 102. Memory system 100 may include a non-volatile storage system interfacing with host 102 (e.g., a mobile computing device). In some cases, memory system 100 may be embedded within host 102. In other cases, memory system 100 may include a memory card.

As depicted, memory system 100 includes a memory chip controller 104 and a memory chip 106. Although a single memory chip 106 is depicted, memory system 100 may include more than one memory chip (e.g., four, eight or some other number of memory chips). Memory chip controller 104 may receive data and commands from host 102 and provide data to host 102. In an embodiment, memory system 100 is used to perform matrix-vector multiplication. In an embodiment, memory system 100 is used to perform matrix-vector multiplication in a neuromorphic computing system.

Memory chip controller 104 may include one or more state machines, page registers, SRAM, decoders, sense amplifiers, and control circuitry for controlling the operation of memory chip 106. The one or more state machines, page registers, SRAM, and control circuitry for controlling the operation of memory chip 106 may be referred to as managing or control circuits.

The managing or control circuits may facilitate one or more memory operations, such as programming, reading (or sensing) and erasing operations. In an embodiment, the managing or control circuits are used to perform multiplication using non-volatile memory cells. Herein, multiplication will be referred to as a type of memory operation.

In some embodiments, the managing or control circuits (or a portion of the managing or control circuits) that facilitate one or more memory array operations, including programming, reading, erasing and multiplication operations, may be integrated within memory chip 106. In some embodiments, the managing or control circuits may include an on-chip memory controller for determining row and column address, bit line, source line and word line addresses, memory array enable signals, and data latching signals.

Memory chip controller 104 and memory chip 106 may be arranged on a single integrated circuit. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. In an embodiment, memory core control circuits 108 include circuits that generate row and column addresses for selecting memory blocks (or arrays) within memory core 110, and generating voltages to bias a particular memory array into a read or a write state. In an embodiment, memory core control circuits 108 include circuits for generating voltages to bias a memory array to perform matrix-vector multiplication using non-volatile memory cells in memory core 110.

Memory chip controller 104 controls operation of memory chip 106. In an embodiment, once memory chip controller 104 initiates a memory operation (e.g., read, write, or multiply), memory core control circuits 108 generate the appropriate bias voltages for bit lines, source lines and/or word lines within memory core 110, and generates the appropriate memory block, row, and column addresses to perform memory operations.

In an embodiment, memory core 110 includes one or more arrays of non-volatile memory cells used to perform matrix-vector multiplication. In an embodiment, memory core 110 includes one or more arrays of SOT non-volatile memory cells used to perform matrix-vector multiplication in a neuromorphic computing system. Memory core 110 may include one or more two-dimensional or three-dimensional arrays of SOT non-volatile memory cells.

In an embodiment, memory core control circuits 108 and memory core 110 are arranged on a single integrated circuit. In other embodiments, memory core control circuits 108 (or a portion of memory core control circuits 108) and memory core 110 may be arranged on different integrated circuits.

In an embodiment, memory core 110 includes a three-dimensional memory array of SOT non-volatile memory cells in which multiple memory levels are formed above a single substrate, such as a wafer. The memory structure may include SOT non-volatile memory that is monolithically formed in one or more physical levels of arrays of non-volatile memory cells having an active area disposed above a silicon (or other type of) substrate.

FIG. 1B depicts an embodiment of memory core control circuits 108. As depicted, memory core control circuits 108 include address decoders 120, voltage generators 122, read/write/multiply circuit 124, and transfer data latch 126. In an embodiment, address decoders 120 generate memory block addresses, as well as row addresses and column addresses for a particular memory block. In an embodiment, voltage generators (or voltage regulators) 122 generate voltages for control lines.

Read/write/multiply circuit 124 includes circuitry for reading and writing non-volatile memory cells in memory core 110. In an embodiment, transfer data latch 126 is used for intermediate storage between memory chip controller 104 (FIG. 1A) and non-volatile memory cells. In an embodiment, transfer data latch 126 has a size equal to a size of a page.

In an embodiment, when host 102 instructs memory chip controller 104 to write data to memory chip 106, memory chip controller 104 writes a page of host data to transfer data latch 126. Read/write/multiply circuit 124 then writes data from transfer data latch 126 to a specified page of non-volatile memory cells.

In an embodiment, when host 102 instructs memory chip controller 104 to read data from memory chip 106, read/write/multiply circuit 124 reads from a specified page of non-volatile memory cells into transfer data latch 126, and memory chip controller 104 transfers the read data from transfer data latch 126 to host 102.

Read/write/multiply circuit 124 also includes circuitry for performing multiplication operations using non-volatile memory cells. In an embodiment, read/write/multiply circuit 124 stores multiplicands (e.g., weights) in the non-volatile memory cells.

In an embodiment, read/write/multiply circuit 124 is configured to apply multiply voltages to SOT non-volatile memory cells that store multiplicands (e.g., weights). As described above, in an embodiment each multiply voltage has a magnitude that represents a multiplier. In an embodiment, the non-volatile memory cell in a node conducts a memory cell current in response to the multiply voltage applied to the non-volatile memory cell. In an embodiment, the magnitude of the non-volatile memory cell current depends on the physical state of the non-volatile memory cell and the magnitude of the multiply voltage.

For example, in an embodiment the magnitude of a SOT non-volatile memory cell current depends on the resistance of the SOT non-volatile memory cell and the voltage applied across two terminals of the SOT non-volatile memory cell. In an embodiment, the magnitude of the non-volatile memory cell current depends on whether the non-volatile memory cell is in a first physical state or a second physical state. Each physical state may be represented by a physical parameter (e.g., a non-volatile memory cell resistance).

In a read operation, after a read voltage is applied the SOT memory cell current may be sensed and compared with a reference current to determine which state the memory cell is in. For example, the magnitude of the output current corresponding to the read voltage may be compared to a reference current to delineate between the two states. However, the multiply voltage could have one of many different magnitudes, depending on what multiplier is desired. Moreover, the memory cell current that results from applying the multiply voltage is not necessarily compared to a reference current.

In an embodiment, read/write/multiply circuit 124 simultaneously applies a corresponding multiply voltage to each node. Each multiply voltage may correspond to an element of an input vector. The current in each bit line generates a vector multiplication result signal that represents multiplication of the first vector by a second vector.

FIG. 1C depicts further details of an embodiment of voltage generator circuits 122, which includes voltage generators for selected control lines 122a, voltage generators for unselected control lines 122b, and signal generators for reference signals 122c. Control lines may include bit lines, source lines and word lines, or a combination of bit lines, source lines and word lines.

Voltage generators for selected control lines 122a may be used to generate program, read, and/or multiply voltages. In an embodiment, voltage generators for selected control lines 122a generates a voltage whose magnitude is based on a multiplier for a mathematical multiplication operation. In an embodiment, the voltage difference between the voltages for two selected control lines is a multiply voltage.

Voltage generators for unselected control lines 122b may be used to generate voltages for control lines that are connected to memory cells that are not selected for a program, read, or multiply operation. Signal generators for reference signals 122c may be used to generate reference signals (e.g., currents, voltages) to be used as a comparison signal to determine the physical state of a memory cell.

In an embodiment, non-volatile memory cells are used to perform matrix-vector multiplication in a neuromorphic computing system. A neuromorphic computing system may be used to implement an artificial neural network.

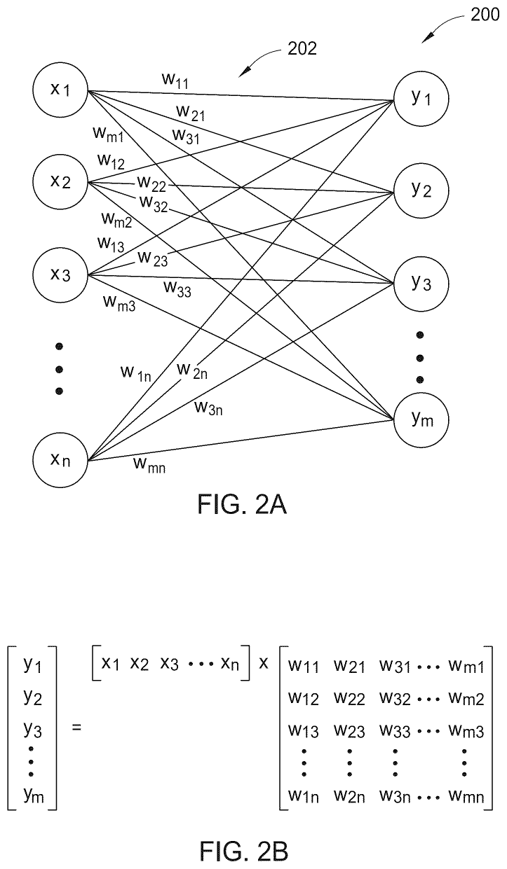

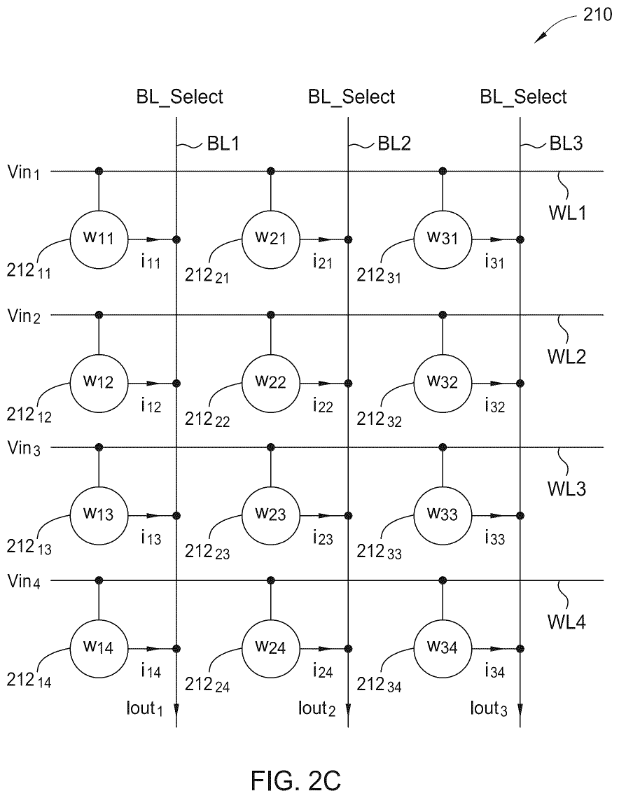

FIG. 2A depicts an example of an artificial neural network or DNN 200 that includes input neurons x₁, x₂, x₃, . . . , xₙ, output neurons y₁, y₂, y₃, . . . , yₘ, and synapses 202 that connect input neurons x₁, x₂, x₃, . . . , xₙ to output neurons y₁, y₂, y₃, . . . , yₘ. In an embodiment, each synapse 202 has a corresponding weight w₁₁, w₁₂, w₁₃, . . . , wₙₘ.

In an embodiment, each input neuron x₁, x₂, x₃, . . . , xₙ has an associated value, each output neuron y₁, y₂, y₃, . . . , yₘ has an associated value, and each weight w₁₁, w₁₂, w₁₃, . . . , wₙₘ has an associated value. The value of each output neuron y₁, y₂, y₃, . . . , yₘ may be determined as follows:

$${y}_{k} = {\sum }_{j = 1}^{n} {x}_{j} {w}_{kj} , j = 1 , 2 , … , m \qquad ( 1 )$$

In matrix notation, equation (1) may be written as y=x^{T}W, where y is an m-element output vector, x is an n-element input vector, and W is an n×m array of weights, as depicted in FIG. 2B.

The matrix-vector multiplication operation depicted in FIG. 2B may be implemented by multiply and accumulate operations, in which each output neuron y₁, y₂, y₃, . . . , yₘ has an associated value equal to the sum of products of each input neuron x₁, x₂, x₃, . . . , xₙ with the corresponding weight w₁₁, w₁₂, w₁₃, . . . , wₙₘ that connects each respective input neuron x₁, x₂, x₃, . . . , xₙ to the output neuron y₁, y₂, y₃, . . . , yₘ.

So, for example, with n=4 and m=3,

$${y}_{1} = {x}_{1} {w}_{11} + {x}_{2} {w}_{12} + {x}_{3} {w}_{13} + {x}_{4} {w}_{14} \qquad ( 2 )$$

$${y}_{2} = {x}_{1} {w}_{21} + {x}_{2} {w}_{22} + {x}_{3} {w}_{23} + {x}_{4} {w}_{24} \qquad ( 3 )$$

$${y}_{3} = {x}_{1} {w}_{31} + {x}_{2} {w}_{32} + {x}_{3} {w}_{33} + {x}_{4} {w}_{34} \qquad ( 4 )$$

In an embodiment, a cross-point memory array is used to perform the multiply and accumulate operations described above. FIG. 2C depicts an example cross-point memory array 210 that may be used to perform the matrix-vector multiplication operation depicted in FIG. 2B, with n=4 and m=3.

Cross-point memory array 210 includes n rows and m columns of nodes 212₁₁, 212₁₂, . . . , 212₃₄. Each row of nodes 212₁₁, 212₁₂, . . . , 212₃₄ is coupled to one of n first conductive lines (e.g., word lines (WL1, WL2, WL3, WL4). Each column of nodes 212₁₁, 212₁₂, . . . , 212₃₄ is coupled to one of m second conductive lines (e.g., bit lines BL1, BL2, BL3). Persons of ordinary skill in the art will understand that cross-point memory arrays may include more or fewer that four word lines, and more or fewer than three bit lines, and more or fewer than twelve nodes.

In an embodiment, each node 212₁₁, 212₁₂, . . . , 212₃₄ of cross-point memory array 210 includes a non-volatile memory cell having an adjustable resistance. In an embodiment, the non-volatile memory cells in nodes 212₁₁, 212₁₂, . . . , 212₃₄ may be programmed to store a corresponding weight or state of an n×m array of weights w₁₁, w₁₂, w₁₃, . . ., w₃₄, respectively. Thus, each node 212₁₁, 212₁₂, . . . , 212₃₄ is labeled with a corresponding weight w₁₁, w₁₂, w₁₃, . . . , w₃₄, respectively, programmed in the corresponding non-volatile memory cell of the node. In an embodiment, each weight w₁₁, w₁₂, w₁₃, . . . , w₃₄ corresponds to a conductance of the non-volatile memory cell in each node 212₁₁, 212₁₂, . . . , 212₃₄, respectively. The weights may be programmed, for example, during a training phase of the neural network. A common training method involves the weights being selectively and/or iteratively updated using an algorithm such as back propagation.

Input voltages Vin₁, Vin₂, Vin₃ and Vin₄ are shown applied to word lines WL1, WL2, WL3, WL4, respectively. The magnitudes of input voltages Vin₁, Vin₂, Vin₃ and Vin₄ correspond to the associated values of input neurons x₁, x₂, x₃ and x₄, respectively. A bit line select voltage (BL_Select) is applied to each bit line to select that bit line. For ease of explanation, it will be assumed that BL_Select is zero volts, such that the voltage across the non-volatile memory cell in each node 212₁₁, 212₁₂, . . . , 212₃₄ is the word line voltage.

In an embodiment, the non-volatile memory cells in nodes 212₁₁, 212₁₂, 212₃₄ conduct currents i₁₁, i₁₂, . . . , i₃₄, respectively. Each of currents i₁₁, i₁₂, i₃₄ is based on the voltage applied to the corresponding non-volatile memory cell and the conductance of the corresponding non-volatile memory cell in the node. This “memory cell current” flows to the bit line connected to the non-volatile memory cell. The memory cell current may be determined by multiplying the word line voltage by the conductance of the non-volatile memory cell.

Stated another way, each non-volatile memory cell current corresponds to the result of multiplying one of the elements of an input vector by the weight stored in the non-volatile memory cell. So, for example, the non-volatile memory cell in node 212₁₁ conducts a current i₁₁ that corresponds to the product Vin₁×w₁₁, the non-volatile memory cell in node 212₁₂ conducts a current i₁₂ that corresponds to the product Vin₂×w₁₂, the non-volatile memory cell in node 212₂₃ conducts a current i₂₃ that corresponds to the product Vin₄×w₂₃, and so on.

Bit lines BL1, BL2, BL3 conduct bit line currents Iout₁, Iout₂, Iout₃, respectively. Each bit line current is the summation of the currents of the memory cells connected to that bit line. For example, bit line current Iout₁=i₁₁+i₁₂+i₁₃+i₁₄, bit line current Iout₂=i₂₁+i₂₂+i2₁₃+i₂₄, and bit line current Iout₃=i₃₁+i₃₂+i₃₃+i₃₄. Thus, each bit line current Iout₁, Iout₂, Iout₃ may be viewed as representing a sum of products of the input vector with corresponding weights in a column of the n×m array of weights:

$${Iout}_{1} = {Vin}_{1} \times {w}_{11} + V i {n}_{2} \times {w}_{12} + {Vin}_{3} \times {w}_{13} + V i {n}_{4} \times {w}_{14} \qquad ( 5 )$$

$${Iout}_{2} = {Vin}_{1} \times {w}_{21} + V i {n}_{2} \times {w}_{22} + V i {n}_{3} \times {w}_{23} + V i {n}_{4} \times {w}_{24} \qquad ( 6 )$$

$${Iout}_{3} = {Vin}_{1} \times {w}_{31} + V i {n}_{2} \times {w}_{32} + V i {n}_{3} \times {w}_{33} + V i {n}_{4} \times {w}_{34} \qquad ( 7 )$$

The magnitudes of bit line currents Iout₁, Iout₂ and Iout₃ constitute elements of an output vector, and correspond to the associated values of output neurons y₁, y₂ and y₃, respectively and constitute the result of the matrix-vector multiplication operation depicted in FIG. 2B. As further discussed below, a separate circuitry (e.g., sense amplifier) takes the current outputs and performs the activation function.

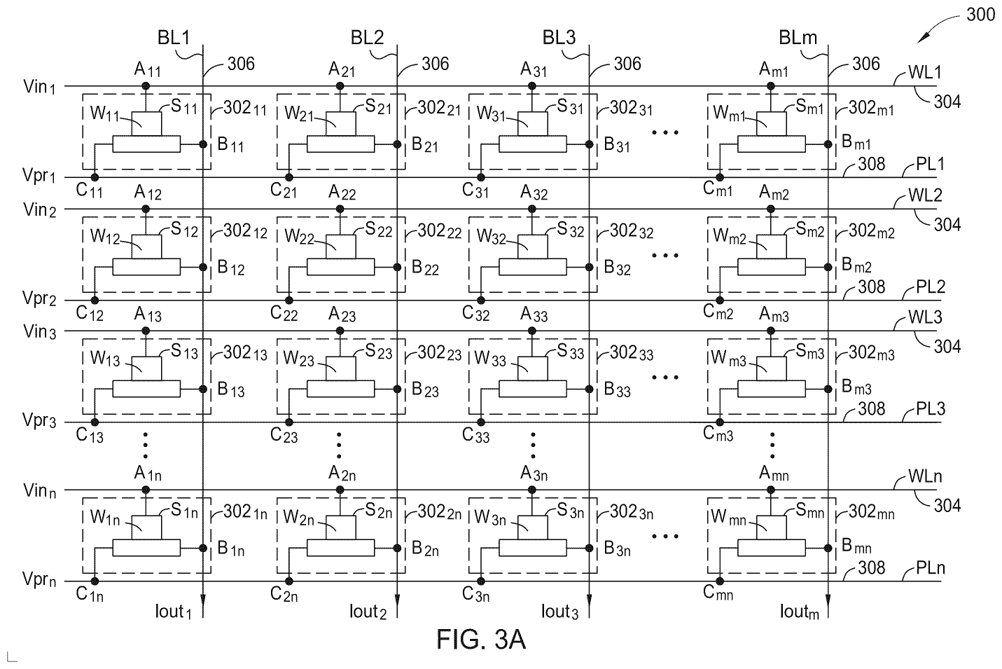

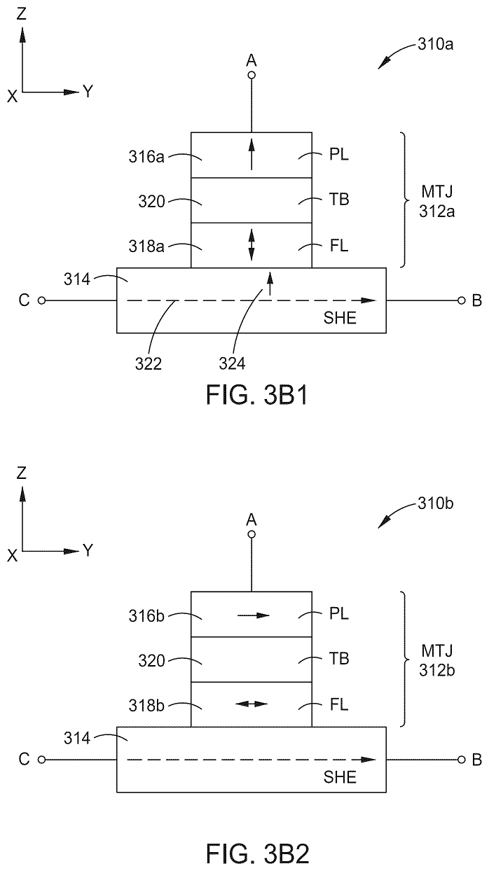

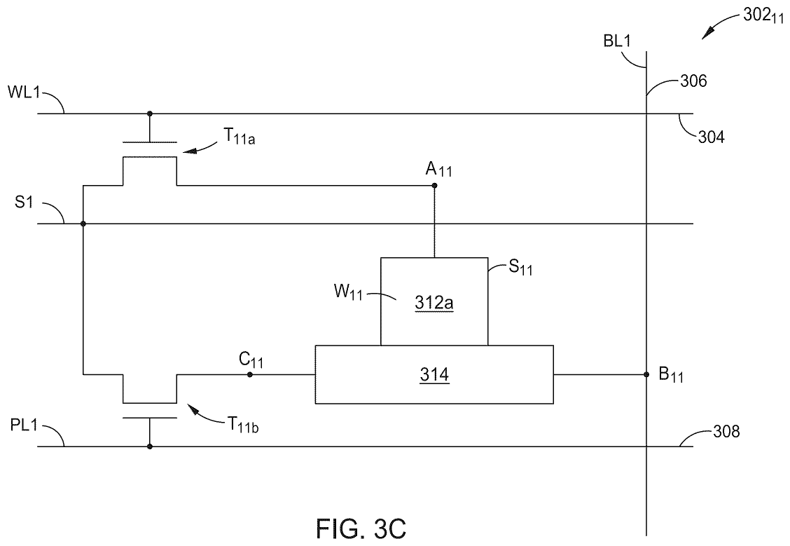

FIG. 3A is a simplified diagram of an embodiment of an apparatus 300 that may be used to perform the matrix-vector multiplication operation depicted in FIG. 2B. In an embodiment, apparatus 300 may be included in memory system 100 (FIG. 1A). In an embodiment, apparatus 300 may be included in memory chip 106 (FIG. 1A). In an embodiment, apparatus 300 may be used to perform multiply accumulate operations, such as matrix-vector multiplication in a neuromorphic computing system.

Apparatus 300 in a cross-point memory array that includes n rows and m columns of nodes 302₁₁, 302₁₂, . . . , 302ₘₙ. Apparatus 300 will also be referred to herein as cross-point memory array 300. In an embodiment, each of nodes 302₁₁, 302₁₂, . . . , 302ₘₙ includes a corresponding non-volatile memory cell S₁₁, S₁₂, . . . , Sₘₙ, respectively. In other embodiments, cross-point memory array 300 may include more than one non-volatile memory cell per node.

Each row of nodes 302₁₁, 302₁₂, . . . , 302ₘₙ is coupled to one of n first conductive lines 304, also referred to herein as word lines WL1, WL2, . . . , WLn. For example, the row of nodes 302₁₁, 302₂₁, 302₃₁, . . . , 302ₘ₁ is coupled to word line WL1, the row of nodes 302₁₃, 302₂₃, 302₃₃, . . . , 302ₘ₃ is coupled to word line WL3, and so on.

In an embodiment, each column of nodes 302₁₁, 302₁₂, . . . , 302ₘₙ is coupled to one of m second conductive lines 306, also referred to herein as bit lines BL1, BL2, . . . , BLm. For example, the column of nodes 302₁₁, 302₁₂, 302₁₃, . . . , 302₁ₙ is coupled to bit line BL1, the column of nodes 302₂₁, 302₂₂, 302₂₃, . . . , 302₂ₙ is coupled to bit line BL2, and so on.

In an embodiment, each row of nodes 302₁₁, 302₁₂, . . . , 302ₘₙ is coupled to one of n third conductive lines 308, also referred to as programming lines PL1, PL2, . . . , PLn. For example, the row of nodes 302₁₁, 302₂₁, 302₃₁, . . . , 302ₘ₁ is coupled to programming line PL1, the row of nodes 302₁ₙ, 302₂ₙ, 302₃ₙ, . . . , 302ₘₙ is coupled to programming line PLn, and so on. The programming lines PL1, PL2, . . . , PLn program a weight or state of each volatile memory cell S₁₁, S₁₂, . . . , Sₘₙ.

Each non-volatile memory cell S₁₁, S₁₂, . . . , Sₘₙ has a first terminal A₁₁, A₁₂, . . . , Aₘₙ, respectively, coupled to one of the n word lines WL1, WL2, . . . , WLn, a second terminal B₁₁, B₁₂, . . . , Bₘₙ, respectively, coupled to one of the m bit lines BL1, BL2, . . . , BLm, and a third terminal C₁₁, C₁₂, . . . , Cₘₙ, respectively, coupled to one of the n programming lines PL1, PL2, . . . , PLn. To simplify this discussion and to avoid overcrowding the diagram, access devices are not depicted in FIG. 3A.

For example, non-volatile memory cell S₁₁ has a first terminal A₁₁ coupled to word line WL1, a second terminal B₁₁ coupled to bit line BL1, and a third terminal C₁₁ coupled to programming line PL1. Likewise, non-volatile memory cell S₃₂ has a first terminal A₃₂ coupled to word line WL2, a second terminal B₃₂ coupled to bit line BL3, and a third terminal coupled C₃₂ to programming line PL2.

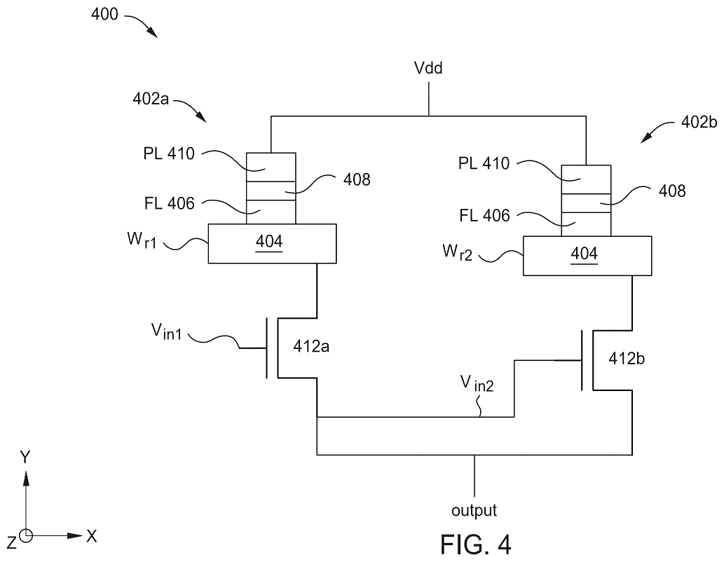

In the following figures, various non-volatile cell embodiments for implementing a multi-weight state SOT DNN approach are disclosed. Briefly a ferromagnetic (FM) free layer with domain walls in FIGS. 4-8B provide the mechanisms for storing multi-weight states, and such a FM layer can be implemented in various memory cells shown in FIGS. 3B1-3C. FIGS. 3B1-3C disclose various magnetic tunnel junction (MTJ) based SOT cell embodiments for leveraging the magneto-resistive property of the MTJ for reading out (i.e., multiplying) the weight states.

The MTJ approach will be described first using FIGS. 3B1-3B2, and FIG. 3C.

In an embodiment, each non-volatile memory cell S₁₁, S₁₂, . . . , Sₘₙ is a spin-orbit torque (SOT) magnetoresistive random-access memory (MRAM) non-volatile memory cell, such as the example SOT MRAM non-volatile memory cell 310a depicted in FIG. 3B1. SOT MRAM non-volatile memory cell 310a includes a first terminal A, a second terminal B, a third terminal C, a MTJ 312a, and a Spin Hall Effect (SHE) or SOT layer 314.

MTJ 312a includes a reference (or pinned) layer (PL) 316a, a free layer (FL) 318a, and a tunnel barrier (TB) 320 positioned between pinned layer 316a and free layer 318a. Tunnel barrier 320 is an insulating layer, such as magnesium oxide (MgO) or other insulating material. Pinned layer 316a is a ferromagnetic layer with a fixed direction of magnetization. Free layer 318a is a ferromagnetic layer and has a direction of magnetization that can be switched.

Pinned layer 316a is usually a synthetic antiferromagnetic layer which includes several magnetic and non-magnetic layers, but for the purpose of this illustration is depicted as a single layer 316a with fixed direction of magnetization. Pinned layer 316a and free layer 318a each have a perpendicular direction of magnetization. Accordingly SOT MRAM non-volatile memory cell 310a is also referred to herein as “perpendicular stack SOT MRAM non-volatile memory cell 310a.”

When the direction of magnetization of free layer 318a is parallel to the direction of magnetization of pinned layer 316a, the resistance of perpendicular stack SOT MRAM non-volatile memory cell 310a is relatively low. When the direction of magnetization of free layer 318a is anti-parallel to the direction of magnetization in pinned layer 316a, the resistance of perpendicular stack SOT MRAM non-volatile memory cell 310a is relatively high.

Thus, generally the resistance of perpendicular stack SOT MRAM non-volatile memory cell 310a may therefore be used to store one bit of data. In an embodiment, SOT MRAM non-volatile memory cell 310a may be programmed to either a low resistance ON state or a high resistance OFF state. In an embodiment, the low resistance ON state may be used to represent a first weight value (e.g., “1”), and the high resistance OFF state may be used to represent a second weight value (e.g., “0”). The data (“0” or “1”) in SOT MRAM non-volatile memory cell 310a may be read by measuring the resistance of SOT MRAM non-volatile memory cell 310a. However, according to the domain wall or magnetic shape anisotropy based free layer approaches disclosed, intermediate values between the binary “0” vs “1” may be stored and read-out, providing a mechanism for multi-weight state use in training and inference.

FIG. 3B2 is a cross-sectional view of another SOT MRAM non-volatile memory cell 310b that may be included in each non-volatile memory cell S₁₁, S₁₂, . . . , Sₘₙ (FIG. 3A). SOT MRAM non-volatile memory cell 310b includes first terminal A, second terminal B, third terminal C, a MTJ 312b having a pinned layer PL 316b and a free layer FL 318b that each have a direction of magnetization that is in an in-plane direction, and SHE layer 314. Accordingly SOT MRAM non-volatile memory cell 310b is also referred to herein as “in-plane stack SOT MRAM non-volatile memory cell 310b.”

When the direction of magnetization of free layer 318b is parallel to the direction of magnetization of pinned layer 316b, the resistance of in-plane stack SOT MRAM non-volatile memory cell 310b is relatively low. When the direction of magnetization of free layer 318b is anti-parallel to the direction of magnetization in pinned layer 316b, the resistance of in-plane stack SOT MRAM non-volatile memory cell 310b is relatively high.

Thus, generally the resistance of in-plane stack SOT MRAM non-volatile memory cell 310b may therefore be used to store one bit of data. In an embodiment, SOT MRAM non-volatile memory cell 310b may be programmed to either a low resistance ON state or a high resistance OFF state. In an embodiment, the low resistance ON state may be used to represent a first weight value (e.g., “1”), and the high resistance OFF state may be used to represent a second weight value (e.g., “0”). The data (“0” or “1”) in SOT MRAM non-volatile memory cell 310b may be read by measuring the resistance of SOT MRAM non-volatile memory cell 310b. However, according to the domain wall or magnetic shape anisotropy based free layer approaches disclosed, additional values beyond the binary “0” vs “1” may be stored and read-out, providing a mechanism for multi-weight state use in training and inference.

Referring again to FIG. 3B1, in an embodiment, SHE layer 314 comprises a heavy metal with strong spin orbit coupling and large effective Spin Hall Angle. Examples of heavy metal materials include platinum, tungsten, tantalum, platinum gold (PtAu), bismuth bopper (BiCu). In other embodiments, SHE layer 314 comprises a topological insulator, such as bismuth antimony (BiSb), bismuth selenide (Bi₂Se₃), bismuth telluride (Bi₂Te₃) or antimony telluride (Sb₂Te₃). In particular embodiments, SHE layer 314 comprises BiSb with (012) orientation, which is a narrow gap topological insulator with both giant Spin Hall Effect and high electrical conductivity. In other embodiments, SHE layer 314 comprises a topological semi-metal (TSM) material, such as BiSb, YPtBi, FeSi, or CoSi.

The spin of an electron is an intrinsic angular momentum. In a solid, the spins of many electrons can act together to affect the magnetic and electronic properties of a material, for example endowing it with a permanent magnetic moment as in a ferromagnet. In many materials, electron spins are equally present in both up and down directions. However, various techniques can be used to generate a spin-polarized population of electrons, resulting in an excess of spin up or spin down electrons, to change the properties of a material. This spin-polarized population of electrons moving in a common direction through a common material is referred to as a spin current.

The Spin Hall Effect is a transport phenomenon that may be used to generate a spin current in a sample carrying an electric current. The spin current is in a direction perpendicular to the plane defined by the electrical current direction and the spin polarization direction. The spin polarization direction of such a SHE-generated spin current is in the in-plane direction orthogonal to the electrical current flow.

For example, an electrical current 322 through SHE layer 314 (from third terminal C to second terminal B) results in a spin current 324 being injected up into free layer 318a, and having a direction of polarization into the page. Spin current 324 injected into free layer 318a exerts a spin torque (or “kick”) on free layer 318a, which causes the direction of magnetization of free layer 318a to oscillate in the y-z plane or to be changed entirely. This can be leveraged for programming the weight state in the free layer during the training phase.

In an embodiment, during a “programming phase,” each SOT MRAM non-volatile memory cell S₁₁, S₁₂, . . . , Sₘₙ is programmed to store a corresponding weight of an n×m array of weights w₁₁, w₁₂, w₁₃, . . . , wₙₘ, respectively. For example, any suitable programming may be used to store weights w₁₁, w₁₂, w₁₃, . . . , wₙₘ in SOT MRAM non-volatile memory cell S₁₁, S₁₂, . . . , Sₘₙ, respectively. As described above, in an embodiment, each of weights w₁₁, w₁₂, w₁₃, . . . , wₙₘ can represent one of several states in a multi-state weight scheme.

After SOT MRAM non-volatile memory cells S₁₁, S₁₂, . . . , Sₘₙ have been programmed with weights w₁₁, w₁₂, w₁₃, . . . , wₙₘ, respectively, e.g., as part of training a neural network, cross-point memory array 300 may be used during an “inferencing phase” to perform the matrix-vector multiplication operation depicted in FIG. 2B. In particular, multiply voltages Vin₁, Vin₂, . . . , Vinₙ are applied to word lines WL1, WL2, . . . , WLn, respectively. In an embodiment, read/write/multiply circuit 124 is configured to apply multiply voltages Vin₁, Vin₂, . . . , Vinₙ to word lines WL1, WL2, . . . , WLn, respectively. The magnitudes of voltages Vin₁, Vin₂, . . . , Vinₙ correspond to the associated values of input neurons x₁, x₂, . . . , xₙ, respectively, and hence multiply voltages Vin₁, Vin₂, . . . , Vinₙ constitute an n-element input vector (multiply vector).

In an embodiment with use of MTJ based cell of FIGS. 3B1-B2, during the inferencing phase, third conductive lines 308 (programming lines PL1, PL2, . . . , PLn) are not used, and may be floated. In addition, for simplicity it will be assumed that bit line select voltages of 0 volts are applied to each of bit lines BL1, BL2, . . . , BLm to select those bit lines. In an embodiment, read/write/multiply circuit 124 is configured to apply bit line select voltages of 0 volts to bit lines BL1, BL2, . . . , BLm.

During the inferencing phase, each SOT MRAM non-volatile memory cell S₁₁, S₁₂, . . . , Sₘₙ conducts a memory cell current that corresponds to the result of multiplying one of the elements of the n-element input vector (multiply vector) by the corresponding weight stored in the non-volatile memory cell. For example, SOT MRAM non-volatile memory cell S₁₁ conducts a memory cell current that corresponds to the product Vin₁×w₁₁, SOT MRAM non-volatile memory cell S₁₂ conducts a memory cell current that corresponds to the product Vin₂×w₁₂, SOT MRAM non-volatile memory cell S₂₃ conducts a memory cell current that corresponds to the product Vin₃×w₂₃, and so on.

During the inferencing phase, the memory cell currents in SOT MRAM non-volatile memory cells S₁₁, S₁₂, . . . , Sₘₙ flow to the bit line BL1, BL2, . . . , BLm connected to the memory cell. Bit lines BL1, BL2, . . . , BLm conduct bit line currents Iout₁, Iout₂, . . . , Ioutₘ, respectively. Each bit line current is the summation of the memory cell currents of the memory cells connected to that bit line. Thus, each bit line current Iout₁, Iout₂, . . . , Ioutₘ may be viewed as representing a sum of products of the multiply vector with corresponding weights in a column of the n×m array of weights

$${Iout}_{1} = {Vin}_{1} \times {w}_{11} + V i {n}_{2} \times {w}_{12} + … {Vin}_{n} \times {w}_{1 n} \qquad ( 8 )$$

$${Iout}_{2} = {Vin}_{1} \times {w}_{21} + V i {n}_{2} \times {w}_{22} + … {Vin}_{n} \times {w}_{2 n} \qquad ( 9 )$$

$$…$$

$${Iout}_{m} = V i {n}_{1} \times {w}_{m 1} + V i {n}_{2} \times {w}_{m 2} + … {Vin}_{n} \times {w}_{m n} \qquad ( 10 )$$

The magnitudes of bit line currents Iout₁, Iout₂, . . . , Ioutₘ constitute elements of an m-element output vector, and correspond to the associated values of output neurons y₁, y₂, . . . , yₘ, respectively, and constitute the result of the matrix-vector multiplication operation depicted in FIG. 2B.

The magnitude of each individual bit line current Iₖ represents a vector-vector multiplication result. That is, the magnitude of bit line current Iₖ represents the result of multiplying the input vector Vin₁, Vin₂, . . . , Vinₙ by the k-th column vector of the n×m array of weights w₁₁, w₁₂, w₁₃, . . . , wₙₘ.

Collectively, bit line currents Iout₁, Iout₂, . . . , Ioutₘ represent a result of matrix-vector multiplication. In an embodiment, bit line currents Iout₁, Iout₂, . . . , Ioutₘ represent output neurons y₁, y₂, y₃, . . . , yₘ, respectively, of artificial neural network 200 of FIG. 2A. Because one node SOT MRAM non-volatile memory cell S₁₁, S₁₂, . . . , Sₘₙ in each column is connected to the same first conductive line 308, the matrix-vector multiplication is very efficient. Essentially, m vector-vector multiplications are performed in parallel.

In an embodiment, a sense amplifier is used to compare the magnitude of each bit line current Iout₁, Iout₂, . . . , Ioutₘ to a reference current. The sense amplifier may output a signal (e.g., one bit of information) that indicates whether the magnitude of the bit line current is less than or greater than the reference current. In an embodiment, the magnitude of the bit line current may be input to an activation function in an artificial neural network. The activation function may take various forms (e.g., Rectified Linear Unit (ReLu)) and may involve operations on the bit line current other than comparing to a reference current. In some applications, the activation function outputs a “fire” or “don't fire” signal based on the magnitude of the summed signal.

As described above, to avoid overcrowding the diagram, access devices are not depicted in FIG. 3A. FIG. 3C is a diagram of node 302₁₁ that includes a first access device T₁₁ₐ, a second access device T_{11b}. and a signal line S1. SOT MRAM non-volatile memory cell S₁₁ includes first terminal A₁₁ coupled via first access device T₁₁ₐ to first conductive line 304 (word line WL1), second terminal B₁₁ coupled to second conductive line 306 (bit line BL1), and third terminal C₁₁ coupled via second access device T_{11b} to third conductive line 308 (programming line PL1).

In an embodiment, first access device T₁₁ₐ and second access device T_{11b} are each MOS transistors, although other types of access device may be used. First access device T₁₁ₐ has a first drain/source terminal coupled to signal line S1, a second drain/source terminal coupled to first terminal A₁₁ of SOT MRAM non-volatile memory cell S₁₁, and a control (gate) terminal coupled to first conductive line 304 (word line WL1). Second access device T_{11b} has a first drain/source terminal coupled to signal line S1, a second drain/source terminal coupled to third terminal C₁₁ of SOT MRAM non-volatile memory cell S₁₁, and a control (gate) terminal coupled to third conductive line 308 (programming line PL1). It is noted that FIG. 3C shows one example embodiment, and that other access device configurations are possible.

During inferencing, first conductive line 304 (word line WL1) is HIGH, third conductive line 308 (programming line PL1) is LOW, first access device T₁₁ₐ is ON, second access device T_{11b} is OFF, and multiply voltage Vin₁ is applied to signal line S1 while a bit line select voltage (e.g., 0V) is applied to second conductive line 306 (bit line BL1). As a result, multiply voltage Vin₁ is applied across first terminal A₁₁ and second terminal B₁₁ of SOT MRAM non-volatile memory cell S₁₁, and SOT MRAM non-volatile memory cell S₁₁, conducts a memory cell current that corresponds to the product Vin₁×w₁₁.

Similar programming and inferencing techniques to those described above in connection with SOT MRAM non-volatile memory cell S₁₁ of FIG. 3C may be used for programming and inferencing SOT MRAM non-volatile memory cells S₁₁, S₁₂, . . . , Sₘₙ of FIG. 3A. In an embodiment, each row of SOT MRAM non-volatile memory cells S₁₁, S₁₂, . . . , Sₘₙ is coupled to the same signal line S1 so that all SOT MRAM non-volatile memory cells in the row receive the same multiply voltage Vin₁, Vin₂, . . . , Vinₙ.

FIG. 4 illustrates a cross-sectional view of a SOT cell scheme 400 that may be included in each non-volatile memory cell S₁₁, S₁₂, . . . , Sₘₙ of FIG. 3A, implementing the DNN of FIG. 2A, according to one embodiment. A neural network, such as the DNN 200 of FIG. 2A, may utilize a plurality of the SOT cells 400 for inference.

The SOT cell scheme 400 comprises two SOT cells 402a, 402b connected in series having parallel paths. Each SOT cell 402a, 402b comprises a SOT layer 404, a free layer 406 disposed on the SOT layer 404, a spacer layer 408 disposed on the free layer 406, and a pinned layer 410 disposed on the spacer layer 408. A first programming line (Wᵣ₁) is connected to the SOT layer 404 of the first SOT cell 402a, and a second programming line (Wᵣ₂) is connected to the SOT layer 404 of the second SOT cell 402b. In some embodiments, the first and second programming lines are complementary, such that the program voltage is opposite to one another but with the same magnitude; they are used individually to set the weight of each SOT cell 402a, 402b, but in opposite ways.

The first SOT cell 402a is further connected to a first voltage input line (Vᵢₙ₁) via a first transistor 412a and the second SOT cell 402b is connected to a second voltage input line (Vᵢₙ₂) via a second transistor 412b. The first and second voltage input lines are complementary, where the voltage polarities are opposite but with the same magnitude. The SOT cells 402a, 402b are connected to the same supply current (Vdd) and the same output. Each SOT cell 402a, 402b has the same weight but on opposite sides; collectively, the whole cell 400 (meaning the first and second SOT cells 402a, 402b) has the same weight, and the cell output is the total resistance summation.

The SOT layers 404 may comprise a heavy metal, a topological insulator (TI) material or a topological semi-metal (TSM) material, such as Pt, Ta, W, PtAu, BiCu, Bi₂Te₃, Sb₂Te₃, BiSb, YPtBi, FeSi, or CoSi. Thanks to their giant spin Hall angle, TI and TSM materials having spin-momentum locking surface states are promising for a spin current source. Hence, TI and TSM materials have the potential for ultra-low-power consumption when utilized in SOT cells. The SOT layers 404 each has a thickness in the y-direction of about 10 nm to about 20 nm, and a length in the x-direction of about 10 nm to about 1 μm. The free layers 406 may comprise Co, CoFe, NiFe, CoFeB, CoB, CoHf, CoFePt, Co/Pt, Co/Pd, CoPtCrB, or a combination thereof, have a thickness in the y-direction of about 5 nm to about 20 nm, and a length in the x-direction of about 10 nm to about 1 μm. The spacer layers 408 may comprise an oxide layer such as MgO, AlOx, MgTiO, TiOx, or a combination thereof, where x is a numeral greater than 1, and the pinned layers 410 may comprise CoFeB, CoFe, or Co for in plane magnetized MTJ, or Co/Pt, Co/Pd, and others for a PMA MTJ (where the “/” denotes sublayers).

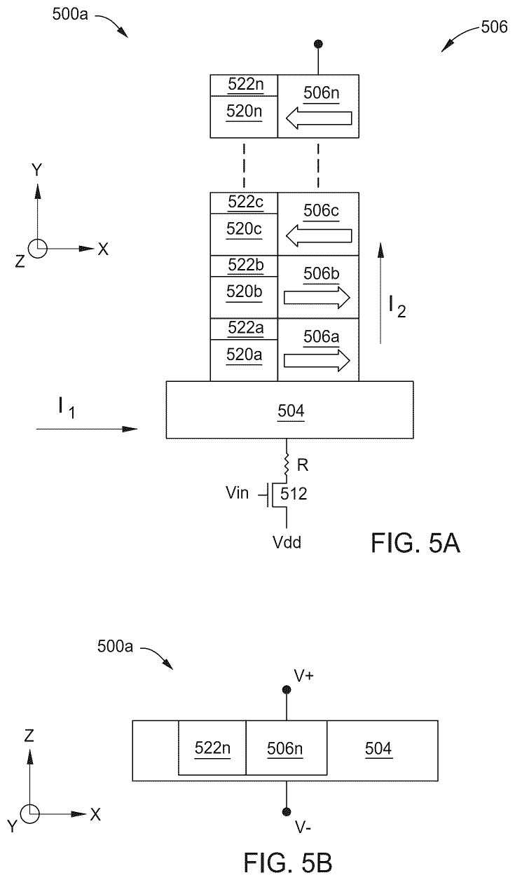

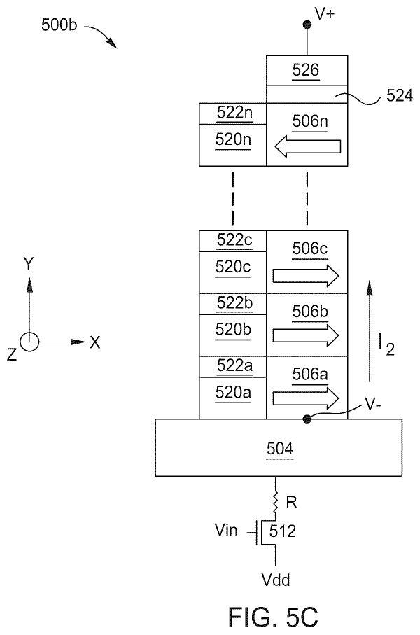

FIGS. 5A-8B illustrate various views of SOT cells 500a, 500b, 600a, 600b, 700, 800 that may be included in each non-volatile memory cell S₁₁, S₁₂, . . . , Sₘₙ of FIG. 3A, or in the SOT cells 310a and 310b of FIGS. 3B1-3B2 or the SOT cell scheme 400 of FIG. 4, implementing the DNN of FIG. 2A, according to various embodiments. A neural network, such as the DNN 200 of FIG. 2A, may utilize a plurality of the SOT cells 500a, 500b, 600a, 600b, 700, 800 for inference.

FIGS. 5A-5C illustrate SOT cells 500a, 500b, according to various embodiments. Additionally, some layers, such as electrodes, are not shown for clarity. FIG. 5A illustrates a cross-sectional view of the SOT cell 500a, FIG. 5B illustrates a top view of the SOT cell 500a, and FIG. 5C illustrates a cross-sectional view of the SOT cell 500b.

The SOT cell 500a of FIG. 5A comprises a SOT layer 504, which may comprise a heavy metal or a TI or TSM material, such as Pt, Ta, W, PtAu, BiCu, Bi₂Te₃, Sb₂Te₃, BiSb, YPtBi, FeSi, or CoSi. A ferromagnetic (FM) layer 506 comprising multiple domains 506a-506n is disposed on the SOT layer 504 in the y-direction. While four magnetic domains 506a, 506b, 506c, 506n are shown, the SOT cell 500a may comprise any number of magnetic domains. The FM layer 506 may comprise Co, CoFe, NiFe, CoFeB, CoB, CoHf, CoFePt, Co/Pt, Co/Pd, CoPtCrB, or a combination thereof.

A low magnetic anisotropy (Ku) oxide layer 520a, 520b, 520c, 520n (collectively referred to herein as low Ku oxide layers 520) is disposed adjacent to and in contact with the FM layer 506 in the x-direction. The first low Ku oxide layer 520a is disposed on the SOT layer 504. By being disposed in contact with the oxide layers 520, the regions that are in contact with the low Ku oxide layers 520 will induce some magnetic anisotropy (low Ku) inside the FM layer 506. The low Ku oxide layers 520a-520n each comprises AIOx, SiN, SiOx, TiOx, or HfOx, where x is a numeral greater than 1, and has a thickness of about 4 nm to about 10 nm. A high Ku oxide layer 522a, 522b, 522c, 522n (collectively referred to herein as high Ku oxide layers 522) is disposed on each low Ku oxide layer 520a-520n in the y-direction and in contact with the FM layer 506 generally, and in particular, with the corresponding domains 506a-506n in the x-direction. The high Ku oxide layers 522a-522n each comprises CrOx, GdOx, MgO, or NiO, where x is a numeral greater than 1, and has a thickness of about 2 nm to about 5 nm. In some embodiments, the low Ku oxide layers 520a-520n have a much greater thickness than the high Ku oxide layers 522a-522n, and the FM domains 506a-506n have a greater thickness than the low Ku oxide layers 520a-520n. Thus, each FM domain 506a-506n is disposed in contact with a low Ku oxide layer 520a-520n and a high Ku oxide layer 522a-522n, and the domain wall or domain boundaries are aligned with the high Ku oxide layers 522a-522n.

By adding two types of oxide layers 520, 522 in contact with the FM layer 506 inside the SOT cell 500a, the magnetic anisotropy of the FM layer 506 is modulated between low magnetic anisotropy (low Hk) and high magnetic anisotropy (high Hk). It is noted that the designation of “low” Hk vs. “high” Hk is relative, and that as long as there is an offset between the induced magnetic anisotropy in the FM by the two oxide layers, similar results can be achieved. Thus, the present disclosure is not necessarily limited to the specific oxides mentioned for the low and high Hk oxide layers in various embodiments, but are directed to any combination of oxide layers where such different magnetic anisotropy can be induced in the FM layer in the various described configurations.

The area with high Ku magnetic anisotropy serves as the pinning sites. As a result, the FM layer 506 is separated into multiple domains 506a-506n, with the domain wall formed between adjacent domains 506a-506n. The positions of each domain wall are generally aligned with the oxide layer where high Ku is induced. The multi-domains induced by such high-low Ku oxide layers 520, 522 enable the FM layer 506 to have different magnetization directions, representing different stored weights (e.g., logical weight value of 0 or 1). For simplicity of description, the magnetization direction and the stored or represented weight may be used interchangeably below.

The FM domains 506a-506n may be considered one FM layer that is partitioned into sub-FM layers 506a-506n due to the formation of the domain walls. Initially, each FM domain 506a-506n has, for example, a magnetization direction pointing in the-x-direction, or representing a stored weight of 1. To set the weight of the first FM layer 506a that is disposed in contact with the SOT layer 504, a first current Ii is applied to the SOT layer 504 in the x-direction. The in-plane current applied to the SOT layer 504 switches the magnetization of the first domain 506a such that the magnetization direction points in the x-direction, effectively changes the represented weight from 1 to 0. This is based on the principle of SOT switching.

To set the weight of the additional FM domains 506b-506n, a second current I₂ is applied vertically in the y-direction. The domain wall will be moved, hence the magnetization direction (and thus stored weight) of the additional FM domains 506b-506n is changed using the spin-transfer torque (STT) effect. The amount of time or the amount of the second current applied then changes the weights of the additional FM domains 506b-506n sequentially. For example, a small amount of I₂ applied, or applied for a short amount of time, would result in the second FM domain 506b switching to have a magnetization direction pointing in the x-direction or a weight of 0, but the upper FM domains 506c-506n would remain unchanged, like shown in FIG. 5A. A greater amount of I₂ applied, or for a longer time, would result in more FM domains 506b, 506c both switching, as shown in FIG. 5C. The domain walls created by the high Ku oxide layers 522a-522n enable the second current to selectively switch some FM domains 506a-506n, without switching all of the FM domains 506a-506n.

Thus, in an example SOT cell 500a comprising four FM domains 506a-506n, five total logical weight states are possible, where each binary digit of the following numbers represents a state or weight of each of the FM domains 506a-506n: 1) 1111; 2) 0111; 3) 0011; 4) 0001; or 5) 0000. This is provided as an example and other schemes of encoding weight are possible. Utilizing a SOT cell 500a having multiple domains enables multi-state weight as compared to binary weight (BNN) and improves the accuracy of a neural network being implemented in the SOT cell.

FIG. 5B illustrates a top view of the SOT cell 500a. As shown in FIG. 5B, voltage leads V+ and V− are connected to the SOT layer 504 for inference (i.e., reading). A transistor 512 is further coupled to the SOT layer 504. The transistor 512 (shown in FIG. 5A) allows an input current (Vin) and a supply current (Vdd) to be applied to the SOT cell 500a. A variable resistance R controls the amount of current applied. To read the weights or states of the FM domains 506a-506n, a small amount of current is applied vertically in the y-direction. The small amount of current is low enough not to disturb the weights or states of the FM domains 560a-506n. Based on the inverse Hall effect and/or the Anomalous Hall effect, the states of the FM layer 506 is read out in-plane to the SOT layer 504 using the voltage leads.

FIG. 5C illustrates a SOT cell 500c, according to another embodiment. The SOT cell 500b is similar to the SOT cell 500a of FIG. 5A; however, the SOT cell 500b further comprises a tunnel barrier layer 524 disposed on the top of the FM layer 506, and a pinned layer 526 disposed on the tunnel barrier layer 524. The pinned layer 526 is a ferromagnetic layer with a fixed direction of magnetization. The pinned layer 526 is often a synthetic antiferromagnetic layer which includes several magnetic and non-magnetic layers. The pinned layer 526 may comprise CoFeB, CoFe, or Co for in plane magnetized MTJ, or Co/Pt, Co/Pd, and others for a PMA MTJ. The weights or states of each FM domains 506a-506n are set as discussed above in FIG. 5A. However, to read the weights or states of the FM domains 506a-506n, a small amount of current is applied vertically in the y-direction. The small amount of current is low enough not to disturb the weights or states of the FM domains 560a-506n. Based on the tunnel magnetoresistance (TMR) effect or giant magnetoresistance (GMR) effect, the states of the FM domains 506a-506n are read out vertically using the voltage leads.

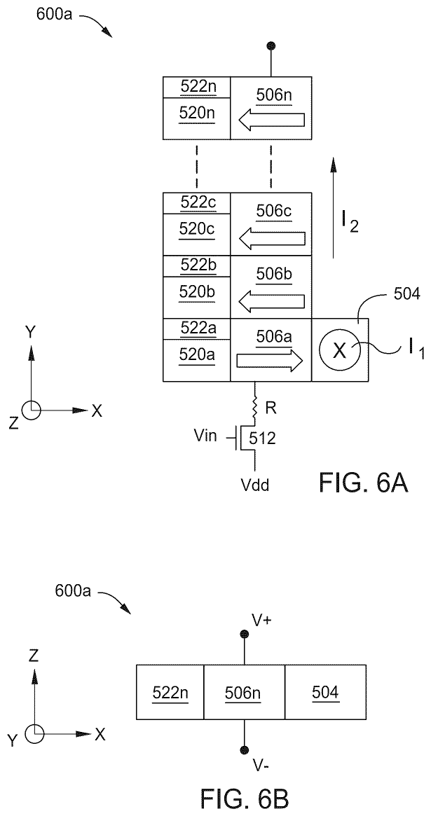

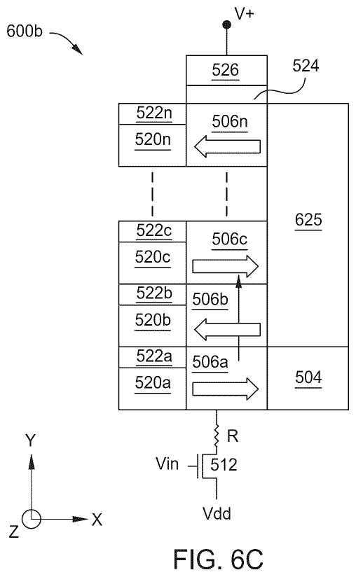

FIGS. 6A-6C illustrate SOT cells 600a, 600b, according to various embodiments. Additionally, some layers, such as electrodes, are not shown for clarity. FIG. 6A illustrates a cross-sectional view of the SOT cell 600a, FIG. 6B illustrates a top view of the SOT cell 600a, and FIG. 6C illustrates a cross-sectional view of the SOT cell 600b.

The SOT cell 600a of FIGS. 6A-6B is similar to the SOT cell 500a of FIGS. 5A-5B; however, the SOT layer 504 is disposed adjacent to the FM layer in the region where its thickness (in the y-direction) spans the first low Ku oxide layer 520a and the first high Ku oxide layer 522a, where only the first magnetic domain 506a is substantially covered by SOT layer 504 in the x-direction, and that the SOT layer 504 extends alongside the first FM domain 506a in the z-direction. The first low Ku oxide layer 520a is not disposed in contact with the SOT layer 504. Setting the weights of the FM domains 506a-560n is the same as described above in FIG. 5A. However, the first current I₁ is applied to the SOT layer 504 in the z-direction or into the page. A second current I₂ is then applied vertically in the y-direction through the FM layer 506 to drive domain wall movement and change the additional domain states 506b-506n. An optional insulating layer 625 may be disposed on the SOT layer 504, as shown in FIG. 6C.

To read the weights or states of the FM domains 506a-506n, a small amount of current is applied vertically in the y-direction. The small amount of current is low enough not to disturb the weights or states of the FM domains 560a-506n. Based on the Anomalous Hall effect, the states of the FM domains 560a-506n are read out in-plane to the FM layer 506 using the voltage leads.

The SOT cell 600b of FIG. 6C is similar to the SOT cell 600a of FIG. 6A; however, the SOT cell 600b further comprises a tunnel barrier layer 524 disposed on the top of the FM layer 506, and a pinned layer 526 disposed on the tunnel barrier layer 524. The weights or states of each FM domain 506a-506n are set as discussed above in FIG. 5A. However, to read the weights or states of the FM domains 506a-506n, a small amount of current is applied vertically in the y-direction. The small amount of current is low enough not to disturb the weights or states of the FM domains 560a-506n. Based on the TMR effect or GMR effect, the states of the FM domains 506a-506n are read out vertically using the voltage leads.

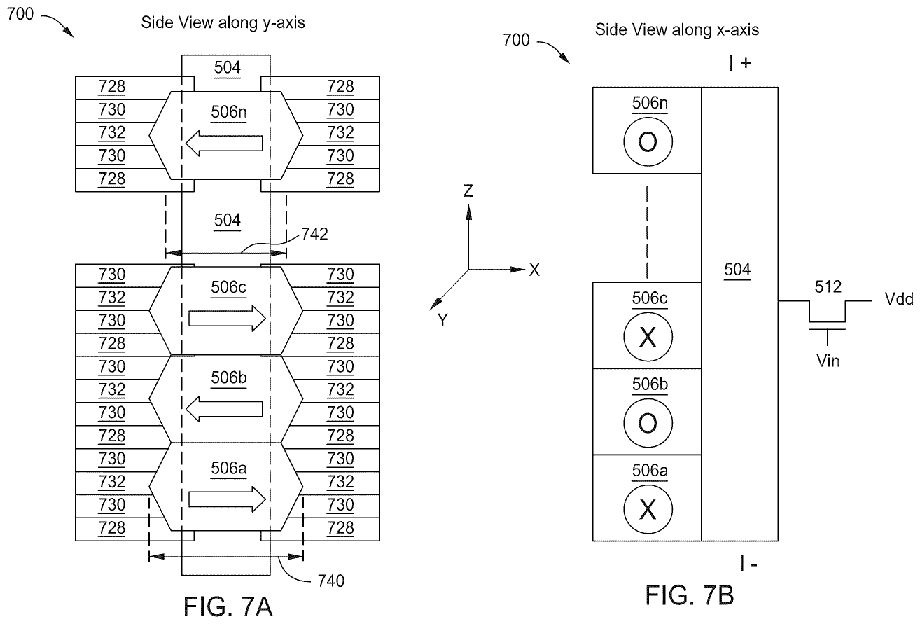

FIGS. 7A-7B illustrate views of an SOT cell 700, according to another embodiment. FIG. 7A illustrates a cross-sectional view, or a side view along the y-axis, and FIG. 7B illustrates a top view, or a side view along the x-axis.

The SOT cell 700 comprises one or more FM domains 506a-506n, where each FM domain 506a-506n is disposed in contact with the SOT layer 504. Each FM domain 506a-506n is disposed adjacent to various etch control layers 728, 730, 732. Specifically, the tops and bottoms of each FM domains 506a-506n are disposed in contact with a first etch control layer 728 having the slowest etching rate. The center of the FM domains 506a-506n are disposed in contact with a second etch control layer 732 having the fastest etching rate. A third etch control layer 730 is disposed between the first and second etch control layers 728, 732, and the third etch control layer 730 has an etching rate between the first etch control layer 728 and the second etch control layer 732. The FM domains 506a-506n may be deposited as one FM layer and then etched to form the various FM domains 506a-506n.

The etch control layers 728-732 are used to shape each FM domain 506a-506n and to create domain walls within the FM layer 506. The ends of the FM domains 506a-506n, or at the boundary of where FM domains 506a-506n are, have a smaller width than the center of the FM layers 506a-506n to create pinned sites where domain walls form. The ends or top and bottom of the FM domains 506a-506n have a width 742 smaller than a width 740 of the center of the FM domains 506a-506n. As such, domain walls are formed at each smaller width 742 or pinned site, enabling each FM domains 506a-506n to have its own weight or state.

The first etch control layer 728 having the slowest etching rate comprises less Si than the second and third etch control layers 730, 732. The second etch control layer 732 having the fastest etching rate comprises more Si than the third etch control layer 730. In one embodiment, the first etch control layer 728 comprises HfO, the second etch control layer 732 comprises SiO₂, and the third etch control layer 730 comprises HfSiO₂.

Varying amounts of current applied in the z-direction through the SOT layer 504 are used to change the state of each of the FM domains 506a-506n. For example, a first write current (I+ to I−) with a large amount of magnitude may be applied to the SOT layer 504 to reset the state of each of the FM domains 506a-506n to 0. A second small amount of write current having an opposite polarity may then be applied to the SOT layer 504 to change the first FM layer 506a to 1 and drive the domain wall movement. The time duration of the second current is set such that the state of one or more FM domains 506a-506n are changed. Thus, the longer the dwell time of the second current that is applied, the more the FM domains 506a-506n weights are changed.

To read the states of the FM domains 506a-506n, an in-plane current (Vin) is applied in the x-direction through the transistor 512 from the supply source (Vdd). The magnitude of current is low enough not to disturb the weights or states of the FM domains. The signal read is read out vertically through the SOT layer 504 and the FM layer 506 based on a combination of Anomalous Hall effect and the inverse spin Hall effect using the same connection leads (I+ and I−) used during the writing stage. The states may then be read out based on the inverse spin Hall effect and the Anomalous Hall effect.

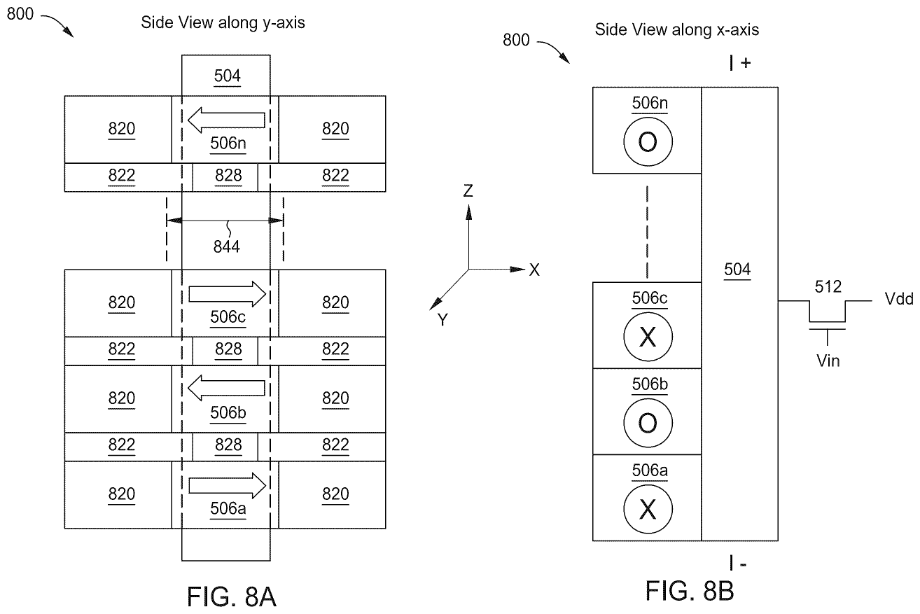

FIGS. 8A-8B illustrate views of a SOT cell 800, according to another embodiment. FIG. 8A illustrates a cross-sectional view, or a side view along the y-axis, and FIG. 8B illustrates a top view, or a side view along the x-axis.

The SOT cell 800 is similar to the SOT cell 600a of FIGS. 6A-6B; however, the oxide layers 520a-520n and 522a-522n have been removed and replaced with etch control layers 820 and 822. A first etch control layer 820 is disposed adjacent to each FM domain 506a-506n. Between each FM domain 506a-506n (i.e., where adjacent FM domains 506a-506n contact one another), a second etch control layer 822 is disposed between first etch control layers 820. The second etch control layer 822 has a slower etching rate than the first etch control layer 820. As a result, the second etch control layer 822 has a greater length in the x-direction than the first etch control layer 820, effectively creating a notch into the FM layer 506. The second etch control layer 822 has a faster etching rate than the first etch control layer 820. This notch can induce a pinning site and create a domain wall in a small portion 828 of the FM layer material, connecting adjacent FM domains 506a-506n. The small portion 828 of the FM layer material may have a width 844 smaller than that of the initial width. The first etch control layer 820 may comprise SiO₂, and the second etch control layer 822 may comprise SiN. The FM domains 506a-506n may be deposited as one FM layer and then etched to form the various FM domains 506a-506n.

The etch control layers 820 and 822 are used to shape each FM domains 506a-506n and to create domain walls between adjacent FM domains 506a-506n. The small portion 828 of FM layer material have a smaller width than the bulk of the FM domains 506a-506n to create pinned sites. As such, domain walls are formed at each small portion 828 of FM layer material or pinned site, enabling each FM domains 506a-506n to have its own weight or state.

Varying amounts of current applied in the z-direction are used to change the state of each of FM domain 506a-506n. For example, a first write current (I+ to I−) with a large amount of magnitude may be applied to the SOT layer 504 to reset the state of each of FM domains 506a-506n to 0. A second small amount of write current having an opposite polarity may then be applied to the SOT layer 504 to change the first FM domain 506a to 1 and drive the domain wall movement. The time duration of the second current is set such that the state of one or more FM domains 506a-506n are changed. Thus, the longer the dwell time of the second current that is applied, the more the FM domains 506a-506n weights are changed.

To read the states of the FM domains 506a-506n, an in-plane current (Vin) is applied in the x-direction through the transistor 512 from the supply source (Vdd). The magnitude of current is low enough not to disturb the weights or states of the FM domains. The signal read is read out vertically through the SOT layer 504 and the FM layer 506 based on a combination of the Anomalous Hall effect and the inverse spin Hall effect using the same connection leads (I+ and I−) used during the writing stage. The states may then be read out based on the inverse spin Hall effect and the Anomalous Hall effect.

Therefore, utilizing a plurality of SOT cells in an artificial neural network or DNN enables the neural network to have ultra-low-power consumption. Furthermore, utilizing a FM layer having two or more domains within each SOT cell can encode weight states beyond binary states, thus improving the accuracy of the neural network.

In one embodiment, a deep neural network (DNN) device, the DNN device comprising an array comprising n rows and m columns of nodes, each row of nodes coupled to one of n first conductive lines, each column of nodes coupled to one of m second conductive lines, each node of the n rows and m columns of nodes comprising a spin orbit torque (SOT) cell, the SOT cell comprising: a SOT layer, a ferromagnetic (FM) layer having a first surface disposed in contact with the SOT layer, the FM layer comprising two or more magnetic domains, two or more first etch control layers disposed in contact with a second surface and a third surface of each of the two or more FM domains, and one or more second etch control layers disposed between each of the two or more FM domains, the one or more second etch control layers being disposed in contact with the second and third surfaces of the two or more FM domains, wherein the one or more second etch control layers have a slower etching rate than the two or more first etch control layers, and a controller configured to store at least one corresponding weight of an n×m array of weights of a neural network using the two or more magnetic domains.

The two or more first etch control layers comprise SiO₂. The one or more second etch control layers comprise SiN. A write current is applied to the SOT layer to set a magnetic state of each of the two or more magnetic domains. The magnetic states of the two or more magnetic domains are read via the inverse spin Hall effect. Each of the two or more magnetic domains has a first width disposed adjacent to the two or more first etch control layers and a second width disposed adjacent to the one or more second etch control layers, the second width being smaller than the first width. The one or more second etch control layers create domain walls between adjacent magnetic domains of the two or more magnetic domains.

In another embodiment, a deep neural network (DNN) device, the DNN device comprising a plurality of spin orbit torque (SOT) cells, each SOT cell comprising: a SOT layer, a ferromagnetic (FM) layer having a first surface disposed in contact with the SOT layer, the FM layer comprising two or more magnetic domains, two or more first etch control layers disposed in contact with a second surface and a third surface of each of the two or more magnetic domains, the two or more first etch control layers being disposed adjacent to a top and bottom of the two or more magnetic domains, and one or more second etch control layers disposed in contact with the second and third surface of the two or more magnetic domains, the one or more second etch control layers being disposed adjacent to a center of each of the two or more magnetic domains, wherein the one or more second etch control layers have a faster etching rate than the two or more first etch control layers, and a controller configured to store a weight of a neural network using the two or more magnetic domains.

The DNN device further comprises two or more third etch control layers disposed in contact with the second and third surfaces of the two or more magnetic domains, the two or more third etch control layers having a slower etching rate than the one or more second etch control layers. The two or more first etch control layers comprise HfO, the one or more second etch control layers comprise SiO₂, and the two or more third etch control layers comprise HfSiO₂. A width of the top and the bottom of each of the two or more magnetic domains is less than a width of the center of each of the two or more magnetic domains. A write current is applied to the SOT layer to set a magnetic state of each of the two or more magnetic domains. The magnetic states of the two or more magnetic domains are read via the inverse spin Hall effect and the Anomalous Hall effect. The two or more first etch control layers create domain walls between adjacent magnetic domains of the two or more magnetic domains.

In yet another embodiment, a spin orbit torque (SOT) cell comprising: a SOT layer, a ferromagnetic (FM) layer having a first surface disposed in contact with the SOT layer, the FM layer comprising two or more magnetic domains, two or more first etch control layers disposed in contact with a second surface and a third surface of each of the two or more magnetic domains, the two or more first etch control layers being disposed adjacent to a top and bottom of the two or more magnetic domains, and one or more second etch control layers disposed in contact with the second and third surface of the two or more magnetic domains, the one or more second etch control layers being disposed adjacent to a center of each of the two or more magnetic domains, wherein the one or more second etch control layers have a higher Si concentration than the two or more first etch control layers.

The one or more second etch control layers have a faster etching rate than the two or more first etch control layers. The two or more first etch control layers comprise HfO, the one or more second etch control layers comprise SiO₂. The SOT cell further comprises two or more third etch control layers disposed in contact with the second and third surfaces of the two or more magnetic domains, the two or more third etch control layers having a slower etching rate than the one or more second etch control layers, wherein the two or more third etch control layers comprise HfSiO₂. A width of the top and the bottom of each of the two or more magnetic domains is less than a width of the center of each of the two or more magnetic domains, and herein the two or more first etch control layers create domain walls between adjacent magnetic domains of the two or more magnetic domains. A write current is applied to the SOT layer to set a magnetic state of each of the two or more magnetic domains, and wherein the magnetic states of the two or more magnetic domains are read via the inverse spin Hall effect and the Anomalous Hall effect.

While the foregoing is directed to embodiments of the present disclosure, other and further embodiments of the disclosure may be devised without departing from the basic scope thereof, and the scope thereof is determined by the claims that follow.

What is claimed is:

1. A deep neural network (DNN) device, the DNN device comprising:
an array comprising n rows and m columns of nodes, each row of nodes coupled to one of n first conductive lines, each column of nodes coupled to one of m second conductive lines, each node of the n rows and m columns of nodes comprising a spin-orbit torque (SOT) cell, the SOT cell comprising:
a SOT layer;
a ferromagnetic (FM) layer having a first surface disposed in contact with the SOT layer, the FM layer comprising two or more magnetic domains;
two or more first etch control layers disposed in contact with a second surface and a third surface of each of the two or more magnetic domains; and
one or more second etch control layers disposed between each of the two or more magnetic domains, the one or more second etch control layers being disposed in contact with the second and third surfaces of the two or more magnetic domains, wherein the one or more second etch control layers have a slower etching rate than the two or more first etch control layers; and
a controller configured to store at least one corresponding weight of an n x m array of weights of a neural network using the two or more magnetic domains.

2. The DNN device of claim 1, wherein the two or more first etch control layers comprise SiO₂.

3. The DNN device of claim 1, wherein the one or more second etch control layers comprise SiN.

4. The DNN device of claim 1, wherein a write current is applied to the SOT layer to set a magnetic state of each of the two or more magnetic domains.

5. The DNN device of claim 4, wherein the magnetic states of the two or more magnetic domains are read via the inverse spin Hall effect.

6. The DNN device of claim 1, wherein each of the two or more magnetic domains has a first width disposed adjacent to the two or more first etch control layers and a second width disposed adjacent to the one or more second etch control layers, the second width being smaller than the first width.

7. The DNN device of claim 1, wherein the one or more second etch control layers create domain walls between adjacent magnetic domains of the two or more magnetic domains.

8. A deep neural network (DNN) device, the DNN device comprising:
an array a plurality of spin-orbit torque (SOT) cells, each SOT cell comprising:
a SOT layer;
a ferromagnetic (FM) layer having a first surface disposed in contact with the SOT layer, the FM layer comprising two or more magnetic domains;
two or more first etch control layers disposed in contact with a second surface and a third surface of each of the two or more magnetic domains, the two or more first etch control layers being disposed adjacent to a top and bottom of the two or more magnetic domains; and
one or more second etch control layers disposed in contact with the second and third surface of the two or more magnetic domains, the one or more second etch control layers being disposed adjacent to a center of each of the two or more magnetic domains, wherein the one or more second etch control layers have a faster etching rate than the two or more first etch control layers; and
a controller configured to store a weight of a neural network using the two or more magnetic domains.

9. The DNN device of claim 8, further comprising two or more third etch control layers disposed in contact with the second and third surfaces of the two or more magnetic domains, the two or more third etch control layers having a slower etching rate than the one or more second etch control layers.

10. The DNN device of claim 9, wherein the two or more first etch control layers comprise HfO, the one or more second etch control layers comprise SiO₂, and the two or more third etch control layers comprise HfSiO₂.

11. The DNN device of claim 8, wherein a width of the top and the bottom of each of the two or more magnetic domains is less than a width of the center of each of the two or more magnetic domains.

12. The DNN device of claim 8, wherein a write current is applied to the SOT layer to set a magnetic state of each of the two or more magnetic domains.

13. The DNN device of claim 12, wherein the magnetic states of the two or more magnetic domains are read via the inverse spin Hall effect and the Anomalous Hall effect.

14. The DNN device of claim 8, wherein the two or more first etch control layers create domain walls between adjacent magnetic domains of the two or more magnetic domains.

15. A spin-orbit torque (SOT) cell comprising:
a SOT layer;
a ferromagnetic (FM) layer having a first surface disposed in contact with the SOT layer, the FM layer comprising two or more magnetic domains;
two or more first etch control layers disposed in contact with a second surface and a third surface of each of the two or more magnetic domains, the two or more first etch control layers being disposed adjacent to a top and bottom of the two or more magnetic domains; and
one or more second etch control layers disposed in contact with the second and third surface of the two or more magnetic domains, the one or more second etch control layers being disposed adjacent to a center of each of the two or more magnetic domains, wherein the one or more second etch control layers have a higher Si concentration than the two or more first etch control layers.

16. The SOT cell of claim 15, wherein the one or more second etch control layers have a slower etching rate than the two or more first etch control layers.

17. The SOT cell of claim 15, wherein the two or more first etch control layers comprise HfO, the one or more second etch control layers comprise SiO₂.

18. The SOT cell of claim 15, further comprising two or more third etch control layers disposed in contact with the second and third surfaces of the two or more magnetic domains, the two or more third etch control layers having a slower etching rate than the one or more second etch control layers, wherein the two or more third etch control layers comprise HfSiO₂.

19. The SOT cell of claim 15, wherein a width of the top and the bottom of each of the two or more magnetic domains is less than a width of the center of each of the two or more magnetic domains, and herein the two or more first etch control layers create domain walls between magnetic domains of the two or more magnetic domains.

20. The SOT cell of claim 15, wherein a write current is applied to the SOT layer to set a magnetic state of each of the two or more magnetic domains, and wherein the magnetic states of the two or more magnetic domains are read via the inverse spin Hall effect and the Anomalous Hall effect.
